(19) United States
(12) Patent Application Publication
(10) Pub. No.: US 2026/0117378 A1
(43) Pub. Date: Apr. 30, 2026

(54) MANIFOLD STRUCTURE AND SUBSTRATE PROCESSING SYSTEMS USING THE SAME

(71) Applicant: ASM IP Holding B.V., Almere (NL)

(72) Inventors: Nitish Manohar Jangale, Jalgaon (IN); Kishan Ashokbhai Patel, Leuven (BE)

(21) Appl. No.: 19/369,704

(22) Filed: Oct. 27, 2025

Related U.S. Application Data
(60) Provisional application No. 63/713,689, filed on Oct. 30, 2024.

(51) Int. Cl. C23C 16/455

(52) U.S. Cl. CPC C23C 16/45561; C23C 16/45512; C23C 16/45565

(57) ABSTRACT

A manifold structure is presented. For using multiple gases at the same time, the present disclosure presents a manifold comprising a gas inlet part disposed at top of a manifold with a main gas channel placed at a center of the gas inlet part; a plurality of body parts disposed below the gas inlet part along a vertical axis; and a mixing part disposed at a bottom along the vertical axis, the mixing part comprises a plurality of sub gas channels, a main gas channel, and a gas mixing space, wherein the gas inlet part, the plurality of body parts and the mixing part are aligned, wherein each of the body parts comprising a main gas channel at a center, a plurality of sub gas channels disposed around the main gas channel, a side hole used to inject gas into the sub gas channel.

### CROSS-REFERENCE TO RELATED APPLICATIONS

This application claims priority to U.S. Provisional Patent Application Ser. No. 63/713,689 filed Oct. 30, 2024 titled MANIFOLD STRUCTURE AND SUBSTRATE PROCESSING SYSTEMS USING THE SAME, the disclosure of which is hereby incorporated by reference in its entirety.

### FIELD OF INVENTION

The present disclosure relates generally to a manifold used in semiconductor processing, more particularly to a manifold structure that can inject multiple gases at the same time for substrate processing.

### BACKGROUND OF THE DISCLOSURE

A conventional showerhead type reactor may use a limited number of precursors/gases and combination of new precursors/gases may enable a new pathway for process development. So, a new manifold structure without restriction on the number of chemistries may be needed.

Therefore, to satisfy the needs described above, the present disclosure provides a manifold structure which may be constructed and replaced easily and extended number of chemistries.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a manifold used in a substrate processing system for injecting gas for processing substrates, the manifold comprises: a gas inlet part disposed at top of a manifold with a main gas channel placed at a center of the gas inlet part; a plurality of body parts disposed below the gas inlet part along a vertical axis; and a mixing part disposed at a bottom along the vertical axis, the mixing part comprises a plurality of sub gas channels, a main gas channel, and a gas mixing space, wherein the gas inlet part, the plurality of body parts and the mixing part are aligned to prevent a gas leakage between the gas inlet part, the plurality of body parts and the mixing part, wherein each of the body parts comprising a main gas channel at a center, a plurality of sub gas channels disposed around the main gas channel, and a side hole used to inject gas into the sub gas channel.

In an aspect, a cross-sectional shape of the body parts is one of a circle or an n-sided polygon wherein n is equal to or greater than 3.

In an aspect, each of the body parts has more than one side holes.

In an aspect, a radius of the main gas channel is greater than that of the sub gas channel.

In an aspect, each of the body parts has a predetermined thickness.

In an aspect, the sub gas channels in a body part directly attached to the gas inlet part are blocked except sub gas channels connected to corresponding side holes.

In accordance with another embodiment there may be provided, a manifold used in a substrate processing system for injecting gas for processing substrates, the manifold comprises: a main body comprising a main gas channel disposed at a center along a vertical axis, a plurality of sub gas channels around the main gas channel and a plurality of side holes, each of the plurality of side holes connected to each of the sub gas channel and used for injecting gas, and a gas mixing space disposed at a bottom along the vertical axis, wherein the main gas channel and the plurality of sub gas channels are connected to the gas mixing space.

In an aspect, a cross-sectional shape of the main body is one of a circle or an n-sided polygon wherein n is equal to or greater than 3.

In an aspect, the plurality of side holes are placed on the main body and are vertically spaced with predetermined distances.

In an aspect, a shape of the sub gas channels is one of straight line, helical curve, or zig-zag curve.

In an aspect, a radius of the sub gas channels changes.

In accordance with another embodiment there may be provided, a substrate processing system comprising: a susceptor provided with a heater for supporting and heating the substrate; a chamber for enclosing and processing the substrate; a showerhead for letting gas in the chamber; and a manifold attachment hub configured to inject gas to the showerhead for processing the substrate, the manifold attachment hub comprises manifold holes, a gas injection space configured to gather gas from the manifold holes and send the gas to the showerhead, and gas paths configured to connect each of the manifold holes and the gas injection space, and wherein at least one manifold is attached to one of the manifold holes of the manifold attachment hub, the manifold comprising: a gas inlet part disposed at top of a manifold with a main gas channel placed at a center of the gas inlet part; a plurality of body parts disposed below the gas inlet part along a vertical axis; and a mixing part disposed at a bottom along the vertical axis, the mixing part comprises a plurality of sub gas channels, a main gas channel, and a gas mixing space, wherein the gas inlet part, the plurality of body parts and the mixing part are aligned to prevent a gas leakage between the gas inlet part, the plurality of body parts and the mixing part, wherein each of the body parts comprising a main gas channel at a center, a plurality of sub gas channels disposed around the main gas channel and a side hole used to inject gas into the sub gas channel.

In accordance with another embodiment there may be provided, a substrate processing system comprising: a susceptor provided with a heater for supporting and heating the substrate; a chamber for enclosing and processing the substrate; a showerhead for letting gas in the chamber; and a manifold attachment hub configured to inject gas to the showerhead for processing the substrate, the manifold attachment hub comprises manifold holes, a gas injection space configured to gather gas from the manifold holes and send the gas to the showerhead, and gas paths configured to connect each of the manifold holes and the gas injection space, and wherein at least one manifold is attached to one of the manifold holes of the manifold attachment hub, the manifold comprising: a main body comprising a main gas channel disposed at a center along a vertical axis, a plurality of sub gas channels around the main gas channel and a plurality of side holes, each of the plurality of side holes connected to each of the sub gas channel and used for injecting gas, and a gas mixing space disposed at a bottom along the vertical axis, wherein the main gas channel and the plurality of sub gas channels are connected to the gas mixing space.

In an aspect, the cross-sectional shapes of the manifolds attached to each of the manifold holes are different.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 (a) illustrates a top view of a manifold block with square cross-sectional shape and two precursor/gas inlets according to the present disclosure; (b) illustrates a side view embodiment of a manifold structure with a block with square cross-sectional shape and two precursor/gas inlet according to the present disclosure.

FIG. 2 (a) illustrates a top view of a manifold block with regular hexagon cross-sectional shape and two precursor/gas inlets according to the present disclosure; (b) illustrates a side view embodiment of a manifold structure with a block with regular hexagon cross-sectional shape and two precursor/gas inlet according to the present disclosure.

FIG. 3 (a) illustrates a top view of a manifold block with regular octagon cross-sectional shape and two precursor/gas inlets according to the present disclosure; (b) illustrates a side view embodiment of a manifold structure with a block with regular octagon cross-sectional shape and two precursor/gas inlet according to the present disclosure.

FIG. 4 (a) illustrates a top view of a manifold block with square cross-sectional shape and one precursor/gas inlets according to the present disclosure; (b) illustrates a side view embodiment of a manifold structure with a block with a square cross-sectional shape and one precursor/gas inlet according to the present disclosure.

FIG. 5 (a) illustrates a top view of a manifold block with an octagonal cross-sectional shape and one precursor/gas inlets according to the present disclosure; (b) illustrates a side view embodiment of a manifold structure with a block with an octagonal cross-sectional shape and one precursor/gas inlet according to the present disclosure.

FIG. 6 illustrates another embodiment of a substrate processing system using the manifolds according to the present disclosure.

FIG. 7 (a) illustrates top view of a manifold block with circle cross-sectional shape and 4 sub gas channels and two precursor/gas inlets according to the present disclosure; (b) illustrates top view of a manifold block with a circular cross-sectional shape and 4 sub gas channels and one precursor/gas inlets according to the present disclosure; (c) illustrates top view of a manifold block with a circular cross-sectional shape and 6 sub gas channels and two precursor/gas inlets according to the present disclosure; (d) illustrates top view of a manifold block with a circular cross-sectional shape and 6 sub gas channels and one precursor/gas inlets according to the present disclosure; (e) illustrates top view of a manifold block with a circular cross-sectional shape and 8 sub gas channels and two precursor/gas inlets according to the present disclosure; (f) illustrates top view of a manifold block with a circular cross-sectional shape and 8 sub gas channels and one precursor/gas inlets according to the present disclosure.

FIG. 8 illustrates side view of another embodiment of a manifold with helical curved 4 sub gas channels & square cross-sectional shape manifold body according to the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

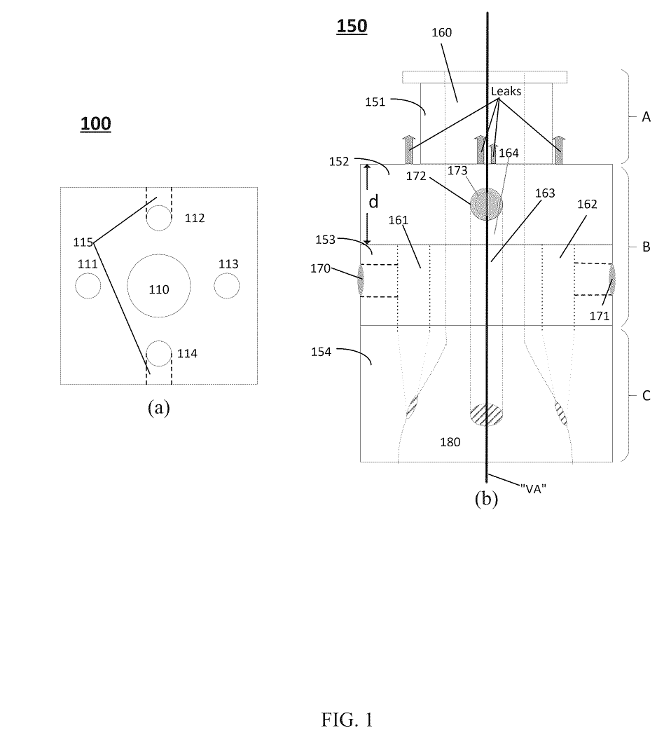

FIG. 1 (a) illustrate a top view of a manifold block 100 with square cross-sectional shape and two precursor/gas inlets according to the present disclosure; (b) illustrates a side view embodiment of a manifold structure 150 with a block with square cross-sectional shape and two precursor/gas inlet according to the present disclosure.

The block 100 may comprise 4 sub gas channels 111, 112, 113, 114 and a main gas channel 110 with a predetermined thickness “d” and 2 side holes 115 for receiving precursors/gases.

The manifold structure 150 may comprise a gas inlet part 151 (“A”) attached on the top of the manifold structure 150, a body part (“B”) comprising two blocks 152, 153 below the gas inlet part 151 aligned to the vertical axis VA, and a mixing part 154 (“C”).

The gas inlet part 151 may be configured to receive a gas with the main gas channel 160. The two blocks 152, 153 are identical ones shown in FIG. 1 (a) and may be constructed so that the lower block 153 may be rotated 90 degrees around “VA” with respect to the block 152. Therefore, the two side holes 172, 173 may be shown directly while the other two side holes 170, 171 may be shown in left and right directions in FIG. 1 (b). The blocks 152, 153 may have a predetermined thickness “d”. The side hole 170 may be connected to the sub gas channel 161 and the side hole 171 may be connected to the sub gas channel 162 in block 153. In block 152, the side hole 172 may be connected to the sub gas channel 163 and the side hole 173 may be connected to the sub gas channel 164.

The sub gas channels 161, 162, 163 and 164 may be aligned from block 152 to the mixing part 154. It may be necessary to block the sub gas channels just below the gas inlet part 151 on the upside of the block 252 (for example, close the upside of the channels with lids) so that the injected gas would not leak from the four sub gas channels as illustrated by the four arrows “Leaks”.

In the mixing part 154, the gas mixing space 180 may be joined by the sub gas channels 161, 162, 163, 164 and the main gas channel 160. The gas from the main & sub gas channels may be gathered & mixed in the gas mixing space 180 to be used in substrate processing.

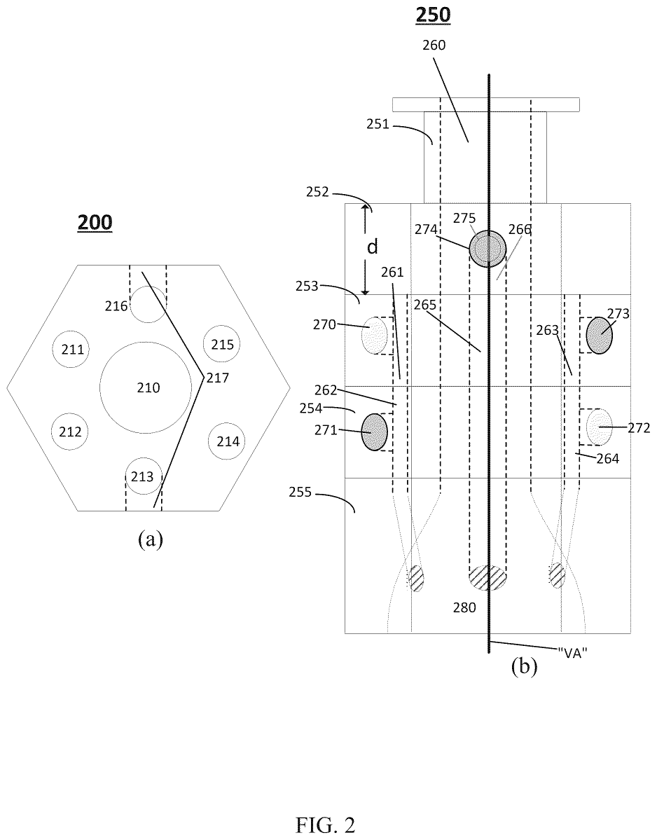

FIG. 2 (a) illustrate a top view of a manifold block 200 with regular hexagon cross-sectional shape and two precursor/gas inlets according to the present disclosure and FIG. 2 (b) illustrates a side view embodiment of a manifold structure 250 with a block with regular hexagon cross-sectional shape and two precursor/gas inlet according to the present disclosure.

The block 200 may comprise 6 sub gas channels 211, 212, 213, 214, 215, 216 and a main gas channel 210 and 2 side holes 217 for receiving precursors/gases.

The manifold structure 250 may comprise a gas inlet part 251 attached on the top of the manifold structure 250, multiple body parts, i.e., three blocks 252, 253, 254 described in FIG. 2 (a) below the gas inlet part 251 aligned to the vertical axis VA, and a mixing part 255.

The gas inlet part 251 may be configured to receive a gas in a main gas channel 260. The three blocks 252, 253, 254 are identical ones shown in FIG. 2 (a) with a thickness ‘d’. An arrangement of the lower blocks 253 & 254 may be such that the lower blocks are rotated 60 degrees & 120 degrees respectively around “VA” with respect to the block 252. Therefore, the two side holes 274, 275 may be shown directly (side hole 275 is directly behind of side hole 274 so it is not drawn) while the other two side holes 270, 273 in body part (block) 253 may be shown in left and right directions just like in FIG. 2 (b) and side holes 271, 272 may be shown in left and right directions just like in FIG. 2 (b).

The blocks 252, 253, 254 may have a predetermined thickness “d”. The side hole 274 may be connected to the sub gas channel 265 and side hole 275 may be connected to the sub gas channel 266 in block 252. In block 253, the side hole 270 may be connected to the sub gas channel 261 and the side hole 273 may be connected to the sub gas channel 263. In block 254, the side hole 271 may be connected to the sub gas channel 262 and the side hole 272 may be connected to the sub gas channel 264.

The sub gas channels 261, 262, 263, 264, 265, 266 may be aligned from block 252 and to the mixing part 255. The gas injected into the manifold should go downward for substrate processing so it may be necessary to block the sub gas channels of the block 252 just below the gas inlet part 251 such as close lids on the above so that the gas injected would not leak from the six sub gas channels.

In the mixing part 255, the gas mixing space 280 may be joined by the sub gas channels 261, 262, 263, 264, 265, 266 and the main gas channel 260. The gas from the main & sub gas channels may be gathered & mixed in the gas mixing space 280 for use in substrate processing.

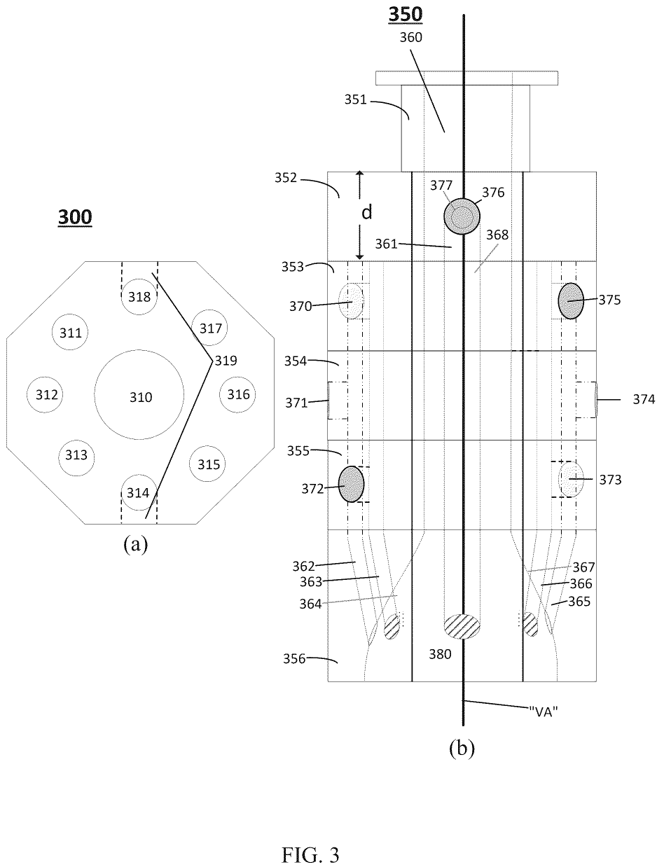

FIG. 3 (a) illustrate a top view of a block 300 with regular octagon cross-sectional shape and two precursor/gas inlets according to the present disclosure and FIG. 2 (b) illustrates a side view embodiment of a manifold structure 350 with a block with regular octagon cross-sectional shape and two precursor/gas inlet according to the present disclosure.

A block (body part) 300 may comprise eight sub gas channels 311, 312, 313, 314, 315, 316, 317, 318 and a main gas channel 310 and two side holes 319 for receiving precursors/gases.

The manifold structure 350 may comprise a gas inlet part 351 attached on the top of the manifold structure 350, multiple body parts, i.e., four blocks 352, 353, 354, 355 described in FIG. 3 (a) below the gas inlet part 351 aligned to the vertical axis VA, and a mixing part 356.

The gas inlet part 351 may be configured to receive a gas in a main gas channel 360. The four blocks 352, 353, 354, 355 are identical to those illustrated in FIG. 3 (a) with a thickness ‘d’. An arrangement of the lower blocks 353, 354, 355 may be such that the lower blocks are rotated 45 degrees, 90 degrees & 135 degrees respectively around “VA” with respect to the block 352.

Therefore, the two side holes 376, 377 in a block 352 may be shown directly (side hole 377 is directly behind of side hole 376) while the side holes 270, 275 in body part (block) 353 & side holes 372, 373 in block 355 may be shown in the left and right sides as shown in FIG. 3 (b). The side holes 371, 374 may not be seen from the front since it is rotated 90 degrees to the left and right respectively just like in FIG. 3 (b).

The blocks 352, 353, 354, 355 may have a predetermined thickness “d”. The side hole 377 may be connected to the sub gas channel 361 and the side hole 376 may be connected to the sub gas channel 368 in the block 352 (The side hole 377 and the sub gas channel 368 are directly behind of the side hole 377 and the sub gas channel 361 respectively therefore not shown). In the block 353, the side hole 370 may be connected to the sub gas channel 364 and the side hole 375 may be connected to the sub gas channel 366. In the block 354, the side hole 371 may be connected to the sub gas channel 362 and the side hole 374 may be connected to the sub gas channel 365. In the block 355, the side hole 372 may be connected to the sub gas channel 363 and side hole 373 may be connected to the sub gas channel 367.

The sub gas channels 361, 362, 363, 364, 365, 366, 367, 368 may be aligned from the block 352 and to the mixing part 356. However, the gas injected into the manifold should go downward for substrate processing so it may be necessary to block the upside of sub gas channels of the block 352 just below the gas inlet part 351 (for example, with lids) so that the gas injected would not leak from the eight sub gas channels.

In the mixing part 356, the gas mixing space 380 may be joined by the sub gas channels 361, 362, 363, 364, 365, 366, 367, 368 and the main gas channel 360. The gas from the main & sub gas channels may be gathered & mixed in the gas mixing space 380 to be used in substrate processing.

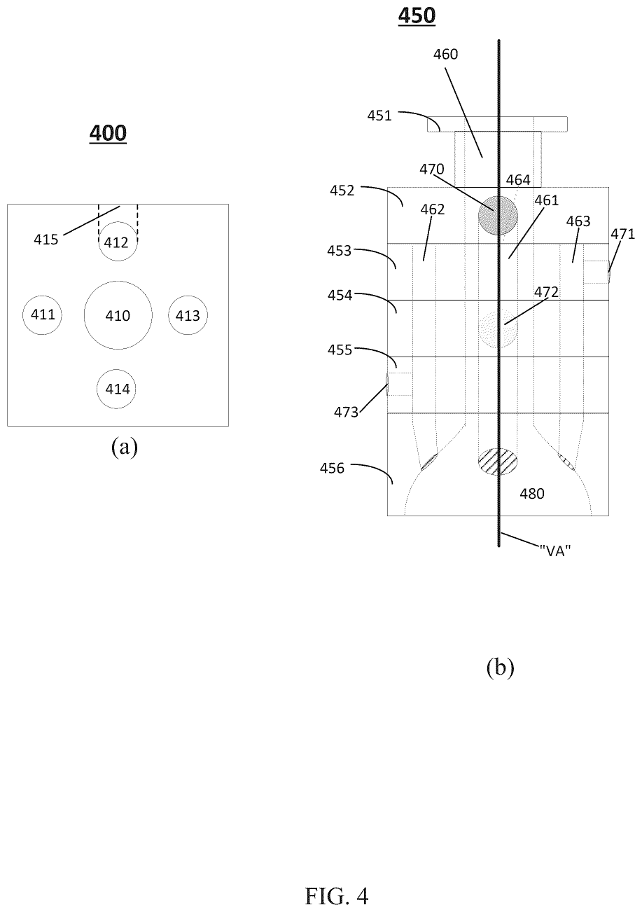

FIG. 4 (a) illustrate a top view of a manifold block 400 with square cross-sectional shape and one precursor/gas inlet according to the present disclosure and FIG. 4 (b) illustrates a side view embodiment of a manifold structure 450 with a block with square cross-sectional shape and one precursor/gas inlet according to the present disclosure.

The block 400 may comprise 4 sub gas channels 411, 412, 413, 414 and a main gas channel 410 with a predetermined thickness “d” and one side hole 415 for receiving precursors/gases. The manifold structure 450 may comprise a gas inlet part 451 attached on the top of the manifold structure 450, four blocks (body parts) 452, 453, 454, 455 described in FIG. 4 (a) below the gas inlet part 451 aligned to the vertical axis VA, and a mixing part 456.

The gas inlet part 451 may be configured to receive a gas in a main gas channel 460. The four blocks 452, 453, 454, 455 are identical ones shown in FIG. 4 (a). An arrangement of the lower blocks 453, 454, 455 may be such that the lower blocks are rotated 90 degrees around “VA” with respect to the block 452. Therefore, the side holes are located 90 degrees rotated from the upper block just like shown in FIG. 4 (b). The side hole 470 may be connected to the sub gas channel 461 in block 452, side hole 471 may be connected to the sub gas channel 463 in block 453. In block 454 the side hole 472 may be connected to the sub gas channel 464 (hidden therefore not drawn) and side hole 473 may be connected to the sub gas channel 462 in block 455.

The sub gas channels 461, 462, 463 and 464 may be aligned from block 452 to the mixing part 456. It may be necessary to block the sub gas channels just below the gas inlet part 451 on the upside of the block 452 (for example, close the upside of the channels with lids) so that the injected gas would not leak from the four sub gas channels.

In the mixing part 456, the gas mixing space 480 may be joined by the sub gas channels 461, 462, 463, 464 and the main gas channel 460. The gas from the main & sub gas channels may be gathered & mixed in the gas mixing space 480 to be used in substrate processing.

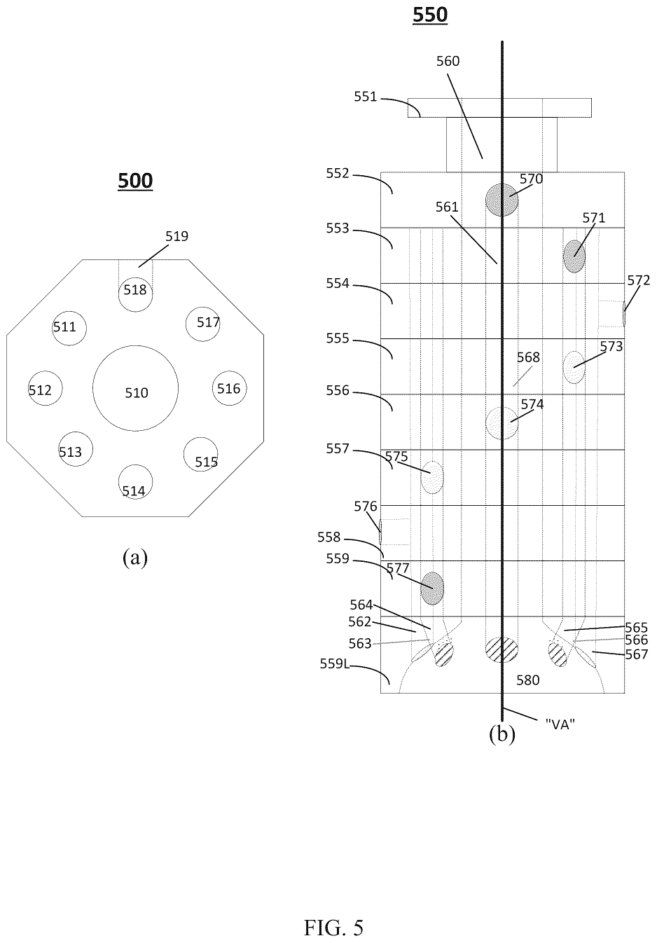

FIG. 5 (a) illustrate a top view of a block 500 with regular octagon cross-sectional shape and one precursor/gas inlets according to the present disclosure and FIG. 2 (b) illustrates an embodiment of a side view of manifold structure 550 with a block with regular octagon cross-sectional shape and one precursor/gas inlet according to the present disclosure.

The block (body part) 500 may comprise eight sub gas channels 511, 512, 513, 514, 515, 516, 517, 518 and a main gas channel 510 and one side hole 519 for receiving precursors/gases.

The manifold structure 550 may comprise a gas inlet part 551 attached on the top of the manifold structure 550, multiple body parts, i.e., eight blocks 552, 553, 554, 555, 556, 557, 558, 559 each of them described in FIG. 5 (a) below the gas inlet part 351 aligned to the vertical axis VA, and a mixing part 559L.

The gas inlet part 551 may be configured to receive a gas in a main gas channel 560. The eight blocks 552, 553, 554, 555, 556, 557, 558, 559 are identical ones shown in FIG. 5 (a) with a thickness ‘d’. An arrangement of the lower blocks 553, 554, 555, 556, 557, 558, 559 may be such that the lower blocks are rotated 45, 90, 135, 180, 225, 270, & 315 degrees respectively around “VA” with respect to the block 552.

The side hole 570 may be connected to the sub gas channel 561 in block 552 and the side hole 571 may be connected to the sub gas channel 565 in block 553. In block 554, the side hole 572 may be connected to the sub gas channel 567, and the side hole 573 may be connected to the sub gas channel 566 in block 555. In block 556, the side hole 574 may be connected to the sub gas channel 568, and the side hole 575 may be connected to the sub gas channel 563 in block 557. In block 558, the side hole 576 may be connected to the sub gas channel 562, and the side hole 577 may be connected to the sub gas channel 564.

The sub gas channels 561, 562, 563, 564, 565, 566, 567, 568 may be aligned from the block 552 and to the mixing part 559L. However, the upside of sub gas channels in block 552 may be closed to prevent the injected gas from leaking through the open channels. So, it may be necessary to block the upside of sub gas channels of the block 552 just below the gas inlet part 551 (for example, with lids) so that the gas injected would not leak from the eight sub gas channels.

In the mixing part 559L, the gas mixing space 580 may be joined by the sub gas channels 561, 562, 563, 564, 565, 566, 567, 568 and the main gas channel 560. The gas from the main & sub gas channels may be gathered & mixed in the gas mixing space 580 to be used in substrate processing.

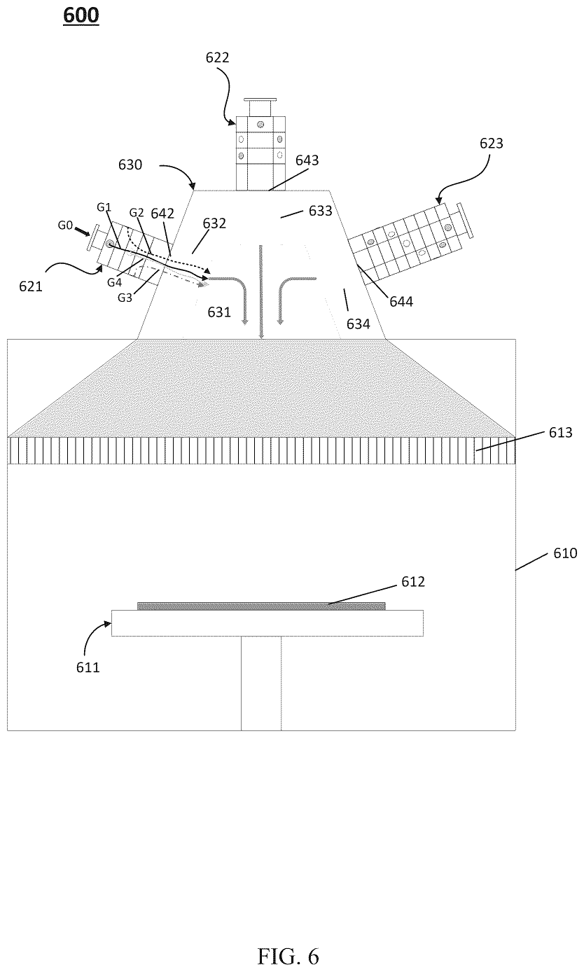

FIG. 6 illustrates another embodiment of a substrate processing system 600 using the manifolds according to the present disclosure.

The system 600 may comprise a chamber 610 for encircling and processing the substrate 612, a susceptor 611 for supporting and heating the substrate 612, a showerhead 613 for letting gas for processing substrates into the chamber 610, and a manifold attachment hub 630 configured to inject gas to the showerhead 613.

The manifold attachment hub 630 may comprise a plurality of manifold holes 642, 643, 644, a gas injection space 631 configured to gather gas from the manifold holes 642, 643, 644 and send the gas to the showerhead 613, and a plurality of gas paths 632, 633, 634 configured to connect each of the manifold holes 642, 643, 644 and the gas injection space 631.

At least one manifold 621, 622, 623 presented in this disclosure may be attached to one of the manifold holes. As shown in FIG. 6, different gases G1, G2, G3, G4 may be injected into the system 600 at the same time with the manifold 621's different sub gas channels and the main gas G0 may be injected into the main gas channel.

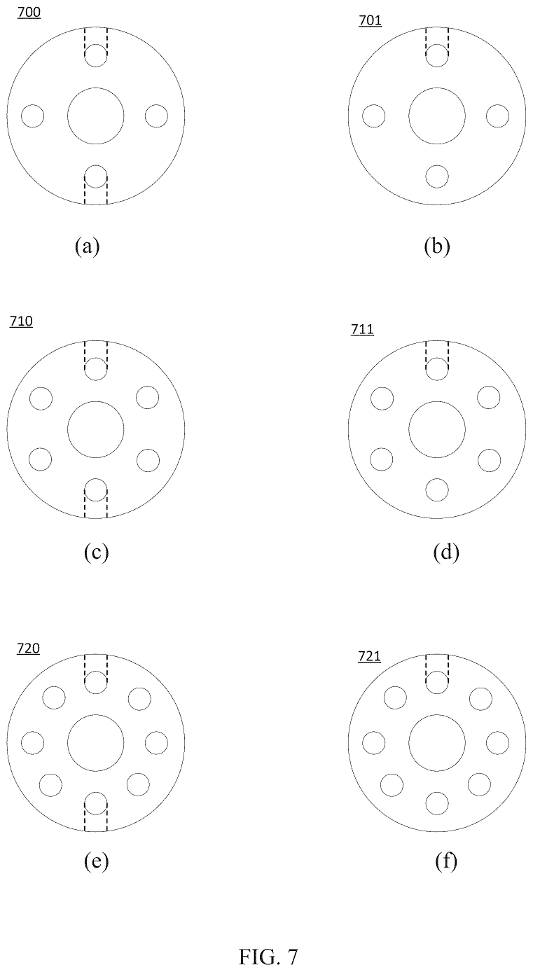

FIGS. 7 (a)˜(f) illustrate another shape of the block.

FIG. 7 (a) illustrates a circle (cross-sectional) shaped block (body part) 700 with 4 sub gas channels around the main gas channel and two side holes per a block.

FIG. 7 (b) illustrates a circle (cross-sectional) shaped block (body part) 701 with 4 sub gas channels around the main gas channel and one side hole per a block.

FIG. 7 (c) illustrates a circle (cross-sectional) shaped block (body part) 710 with 6 sub gas channels around the main gas channel and two side holes per a block.

FIG. 7 (d) illustrates a circle (cross-sectional) shaped block (body part) 711 with 6 sub gas channels around the main gas channel and one side hole per a block.

FIG. 7 (e) illustrates a circle (cross-sectional) shaped block (body part) 720 with 8 sub gas channels around the main gas channel and two side holes per a block.

FIG. 7 (f) illustrates a circle (cross-sectional) shaped block (body part) 721 with 8 sub gas channels around the main gas channel and one side hole per a block.

A manifold made one of the blocks from FIGS. 7 (a)˜(f) has the same technological effect of a manifold made one of the blocks from FIG. 1 (a), FIG. 2 (b), FIG. 3 (a), FIG. 4 (a) or FIG. 5 (a) except that the circle shape may be somewhat more difficult to align the blocks since there would be no external marks to begin the alignment.

All the main gas channels and sub gas channels mentioned above may be fluidly connected in each of the manifolds made of the attached gas inlet part, plurality of body parts (blocks), and mixing part.

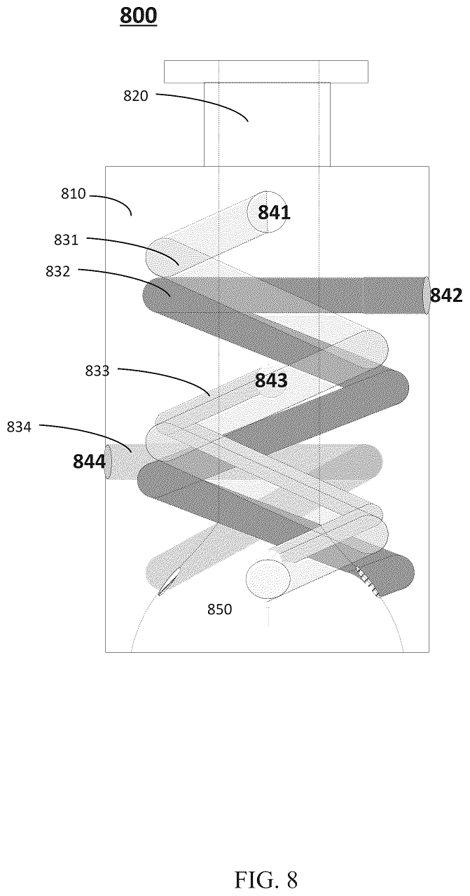

FIG. 8 illustrates a side view of another embodiment of a manifold with helical curved sub gas channels & square cross-sectional shape manifold body according to the present disclosure. Previous embodiments of the present disclosure show sub gas channels shaped straight from the top to the bottom (of the block) and from the start of block to the mixing part but in FIG. 8 the channel's shape is helical and other shapes can be employed for process efficiency. The path shape may be a straight line, a helical curve, or a zig-zag curve.

In FIG. 8, the manifold 800 may comprise a main gas channel 820 disposed at a center along a vertical axis, a plurality of sub gas channels 831, 832, 833, 834 around the main gas channel 820 and a plurality of side holes 841, 842, 843, 844, each of the plurality of side holes 841, 842, 843, 844 connected to each of the sub gas channel 831, 832, 833, 834 respectively and used for injecting gas.

The manifold 800 may also comprise a gas mixing space 850 disposed at a bottom along the vertical axis, wherein the main gas channel 820 and the plurality of sub gas channels 831, 832, 833, 834 are connected to the gas mixing space 850.

FIG. 8 illustrates that the manifold 800 is a singular whole body while the other embodiments illustrated in FIGS. 1-5 comprise an assembly of blocks (i.e., body parts).

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A manifold used in a substrate processing system for injecting gas for processing substrates, the manifold comprises:
a gas inlet part disposed at top of a manifold with a main gas channel placed at a center of the gas inlet part;
a plurality of body parts disposed below the gas inlet part along a vertical axis; and
a mixing part disposed at a bottom along the vertical axis, wherein the mixing part comprises a plurality of sub gas channels, a main gas channel, and a gas mixing space;
wherein the gas inlet part, the plurality of body parts and the mixing part are aligned to prevent a gas leakage between the gas inlet part, the plurality of body parts and the mixing part,
wherein the plurality of body parts comprises a main gas channel at a center, a plurality of sub gas channels disposed around the main gas channel, and a side hole configured to inject a gas into the sub gas channel.

2. The manifold according to claim 1, wherein a cross-sectional shape of the body parts is one of a circle or an n-sided polygon wherein n is equal to or greater than 3.

3. The manifold according to claim 2, wherein each of the body parts has more than one side holes.

4. The manifold according to claim 1, wherein a radius of the main gas channel is greater than that of the sub gas channel.

5. The manifold according to claim 1, wherein each of the body parts has a predetermined thickness.

6. The manifold according to claim 1, wherein the sub gas channels in a body part directly attached to the gas inlet part are blocked except sub gas channels connected to corresponding side holes.

7. A manifold used in a substrate processing system for injecting gas for processing substrates, the manifold comprises:
a main gas channel disposed at a center along a vertical axis;
a plurality of sub gas channels around the main gas channel; and
a plurality of side holes, wherein each of the side holes is connected to a corresponding sub gas channel; and
a gas mixing space disposed at a bottom of the manifold along the vertical axis, wherein the main gas channel and the plurality of sub gas channels are fluidly connected to the gas mixing space.

8. The manifold according to the claim 7, wherein a cross-sectional shape of the manifold is one of a circle or an n-sided polygon wherein n is equal to or greater than 3.

9. The manifold according to the claim 7, wherein the plurality of side holes are placed on the main body and are vertically spaced with predetermined distances.

10. The manifold according to the claim 7, wherein a shape of the sub gas channels is one of a straight line, a helical curve, or a zig-zag curve.

11. The manifold according to the claim 7, wherein a radius of the sub gas channels changes.

12. A substrate processing system comprising:
a susceptor provided with a heater for supporting and heating the substrate;
a chamber for enclosing and processing the substrate;
a showerhead for letting gas in the chamber; and
a manifold attachment hub configured to inject gas to the showerhead for processing the substrate, the manifold attachment hub comprises manifold holes, a gas injection space configured to gather gas from the manifold holes and send the gas to the showerhead, and gas paths configured to connect each of the manifold holes and the gas injection space, and
wherein at least one manifold is attached to one of the manifold holes of the manifold attachment hub, the at least one manifold comprising:
a gas inlet part disposed at top of a manifold with a main gas channel placed at a center of the gas inlet part;
a plurality of body parts disposed below the gas inlet part along a vertical axis; and
a mixing part disposed at a bottom along the vertical axis, the mixing part comprises a plurality of sub gas channels, a main gas channel, and a gas mixing space,
wherein the gas inlet part, the plurality of body parts and the mixing part are aligned to prevent a gas leakage between the gas inlet part, the plurality of body parts and the mixing part,
wherein each of the body parts comprising a main gas channel at a center, a plurality of sub gas channels disposed around the main gas channel, and a side hole used to inject gas into the sub gas channel.

13. A substrate processing system comprising:
a susceptor provided with a heater for supporting and heating the substrate;
a chamber for enclosing and processing the substrate;
a showerhead for letting gas in the chamber; and
a manifold attachment hub configured to inject gas to the showerhead for processing the substrate, the manifold attachment hub comprises manifold holes, a gas injection space configured to gather gas from the manifold holes and send the gas to the showerhead, and gas paths configured to connect each of the manifold holes and the gas injection space, and
wherein at least one manifold is attached to one of the manifold holes of the manifold attachment hub, the manifold comprising:
a main body comprising a main gas channel disposed at a center along a vertical axis, a plurality of sub gas channels around the main gas channel and a plurality of side holes, each of the plurality of side holes connected to each of the sub gas channel and used for injecting gas, and a gas mixing space disposed at a bottom of the manifold along the vertical axis, wherein the main gas channel and the plurality of sub gas channels are fluidly connected to the gas mixing space.

14. The substrate processing system according to claim 12, wherein the cross-sectional shapes of the manifolds attached to each of the manifold holes are different.

15. The substrate processing system according to claim 13, wherein the cross-sectional shapes of the manifolds attached to each of the manifold holes are different.
